(19) United States
(12) Patent Application Publication
(10) Pub. No.: US 2023/0221632 A1
(43) Pub. Date: Jul. 13, 2023

(54) EXPOSURE PATTERN, EXPOSURE MASK USED FOR FORMING SAME, AND METHOD FOR FORMING EXPOSURE PATTERN USING SAME

(71) Applicant: DONGWOO FINE-CHEM CO., LTD., Jeollabuk-do (KR)

(72) Inventors: Jun-Gu LEE, Suwon (KR); Jun-Ha KIM, Pyeongtaek (KR); Dong-Jin SON, Asan (KR); Min-Seok JANG, Pyeongtaek (KR)

(21) Appl. No.: 17/927,229

(22) PCT Filed: Apr. 6, 2021
(86) PCT No.: PCT/KR2021/004272

§ 371 Date: Nov. 22, 2022

(30) Foreign Application Priority Data
May 29, 2020 (KR) 10-2020-0065175

(51) Int. Cl. G03F 1/38

(52) U.S. Cl. CPC G03F 1/38

(57) ABSTRACT

The present disclosure relates to an exposure pattern, an exposure mask, and a method for forming an exposure pattern by the same, and the exposure pattern is an exposure pattern formed by a division exposure, and is characterized by that, in an area where a first exposure area formed by the first exposure and a second exposure area formed by the second exposure overlap each other, an area of a first unit pattern area constituting the first exposure area and an area of a second unit pattern area constituting the second exposure area are different from each other.

### TECHNICAL FIELD

The present disclosure relates to an exposure pattern, an exposure mask used to form the exposure pattern, and a method for forming an exposure pattern using the exposure mask.

The present disclosure relates to an adhesive composition for a semiconductor process, a film for a semiconductor process including the same, and a method for manufacturing a semiconductor package using the same.

### BACKGROUND ART

As the information society advances, a variety of demands for display devices are also increasing, and in response to this, various flat panel display devices such as LCD (Liquid Crystal Display Device), PDP (Plasma Display Panel), ELD (Electro Luminescent Display), VFD (Vacuum Fluoresent Display), OLED (Organic Light Emitting Diodes), and the like have been researched in recent years. Additionally, some have already been utilized as display devices in various equipments.

In order for such display devices to be used in various fields as a general screen display device, the key lies in how well it can realize high-quality images such as high definition, high brightness, and large area even while maintaining the characteristics of light weight, thin shape and low power consumption.

In these display devices, a photolithography process is performed to form various patterns on a substrate, during which an exposure operation is performed. For the exposure operation, an exposure equipment such as a stepper equipment, an aligner equipment, or the like is used.

In the case of using the stepper equipment, a small mask is used due to the characteristics of the equipment, and the exposure operation is performed by dividing the substrate into several shots in such a way that the substrate is exposed while being moved up, down, left and right under the stepper mask.

In the case of using the aligner equipment, the entire substrate is exposed by one shot with one large mask due to the characteristics of the equipment. In this regard, after aligning the aligner mask to the aligner equipment, the substrate is aligned to the aligned aligner mask.

Recently, as image display devices under development become gradually larger in size, the size of a unit panel constituting the image display device has become larger than that of the aligner mask provided in the existing aligner equipment. Thus, the unit panel cannot be exposed with one shot even by such aligner equipment, and the unit panel needs to be further divided into a plurality of areas, each of which is exposed by a corresponding shot.

In this way, for the large-area image display devices, exposure performed through a mask provided in an exposure equipment such as a stepper equipment or an aligner equipment has evolved into the division exposure which, after dividing a unit panel constituting the image display apparatus into a plurality of exposure areas, is performed on each area.

At this time, the unit of one exposure process is called a shot.

Because distortion such as shift, rotation, and distortion occurs in an actual shot, the shots are not precisely aligned to each other, so that a difference in parasitic capacitance or the like between the wiring and the pixel electrode may occur between adjacent shots. Due to this, a difference in brightness occurs at the boundary between pixels corresponding to two shots, and due to such discontinuity between the two adjacent shots, a stitch stain is generated on the screen.

Hereinafter, with reference to the accompanying drawings, a description will be given with respect to a stitch stain of a conventional image display device.

FIG. 1 is a diagram representing a plurality of divided exposure areas included in a single panel, and formed by ideal shot alignment.

In the case of manufacturing a large-sized image display device, it cannot be manufactured by a single shot, so the exposure area is divided to perform the exposure. As shown in FIG. 1, when the shot alignment of the plurality of divided exposure areas is exact, the boundary visibility problem will not occur, but the reality is that no matter how precisely the exposure apparatus is aligned, ideal shot alignment cannot be achieved.

FIG. 2 is a diagram showing a double exposure area or an unexposure area generated due to misalignment of shots generated during an actual division exposure process.

Specifically, due to a shot misalignment, a double-exposed area 12 may be generated as shown in FIG. 2A, and an unexposed area 13 may be generated as shown in FIG. 2B. For this reason, since the brightness changes abruptly around the boundary portion, the boundary portion is recognized by the human eye.

FIG. 3 is a diagram illustrating a part of a conventional division exposure pattern for alleviating such boundary visibility problem.

Specifically, according to Korean Patent No. 10-0502794, in order to solve the shot boundary visibility problem, when a liquid crystal display panel is manufactured by performing the division exposure, an overlapping area is made at the boundary portion between adjacent shots, a mosaic-type gradual pattern is formed in the overlapping area to increase the spatial frequency, and it is attempted to reduce the difference in brightness caused by the stitch error between the two areas by gradually decreasingly or increasingly exposing the areas of the shots of the left and right of the boundary. However, the conventional division exposure pattern also has a problem in that minute discrepancies between shots occur.

FIG. 4 is a diagram illustrating an unexposure area and a double exposure area generated due to the misalignment of the shot in this conventional division exposure pattern in the 9 o'clock direction.

As shown in FIG. 4, Korean Patent No. 10-0502794 also generates the unexposure area 13 and the double exposure area 12 due to the misalignment between shots, so that the area may be visually recognized or there may be problems in pattern formation.

### SUMMARY OF INVENTION

### Technical Problem

The first object of this disclosure is to provide an exposure pattern which can alleviate boundary visibility.

The second object of this disclosure is to provide an exposure mask which can alleviate boundary visibility.

The third object of this disclosure is to provide a method for forming an exposure pattern which can alleviate boundary visibility.

### Solution to Problem

The present disclosure provides an exposure pattern formed by a division exposure, which is characterized by that in an area where a first exposure area formed by a first exposure and a second exposure area formed by a second exposure overlap each other, an area of a first unit pattern area constituting the first exposure area and an area of a second unit pattern area constituting the second exposure area are different from each other. According to the present disclosure, it is possible to alleviate the visibility by controlling generation of a double exposure area or an unexposure area caused by the shot misalignment.

Additionally, in the first aspect of the present disclosure, a ratio of an area of the first unit pattern area and an area of the second unit pattern area may be between 1:0.7 and 1:1.3. According to the first aspect, by appropriately adjusting the ratio of the area of the unit pattern area and the width of the overlapping area according to the capability of the exposure apparatus used for exposure, the generation of the double exposure area or the unexposure area is more effectively controlled, so that the visibility can be alleviated.

Additionally, in the second aspect of the present disclosure, a photo resist (PR) used to form the exposure pattern may be at least one kind selected from the group consisting of positive photo resists and negative photo resists. According to the second aspect, by appropriately adjusting the ratio of the area of the unit pattern area according to the kind of the photo resist (PR) and the kind of the visible portion among the double exposure area or the unexposure area, it is possible to more effectively control the generation of the double exposure area or the unexposure area, thereby alleviating the visibility.

Additionally, the present disclosure provides an exposure mask for use in a division exposure in which an exposure is carried out with an exposure area being divided into a plurality of areas, the exposure mask including:

a non-overlapping exposure portion; a first overlapping exposure portion adjacent to one side of the non-overlapping exposure portion; and

a second overlapping exposure portion adjacent to another side of the non-overlapping exposure portion,

wherein an area of a first sub-pixel included in the first overlapping exposure portion is different from an area of a second sub-pixel included in the second overlapping exposure portion. According to the present disclosure, by forming the exposure pattern using the exposure mask, it is possible to more effectively control the generation of the double exposure area or the unexposure area due to the shot misalignment, thereby alleviating visibility.

Also, according to the third aspect of the present disclosure, the ratio of the area of the first sub-pixel and the area of the second sub-pixel may be between 1:0.7 and 1:1.3. According to the third aspect, by appropriately adjusting the ratio of the area of the sub-pixel and the like according to the capability of the exposure apparatus used for exposure, the generation of the double exposure area or the unexposure area is more effectively controlled, so that the visibility can be alleviated.

Also, the present disclosure provides a method for forming a division exposure pattern with which an exposure is carried out with an exposure area being divided into a plurality of areas, the method including:

forming a first exposure area by performing first exposure using an exposure mask including a non-overlapping exposure portion, a first overlapping exposure portion adjacent to one side of the non-overlapping exposure portion, and a second overlapping exposure portion adjacent to another side of the non-overlapping exposure portion; and

forming a second exposure area by performing second exposure using the exposure mask,

wherein in an area where a first exposure area formed by a first exposure and a second exposure area formed by a second exposure overlap each other, an area of a first unit pattern area constituting the first exposure area and an area of a second unit pattern area constituting the second exposure area are different from each other. According to the present disclosure, by forming the exposure pattern using the exposure mask, it is possible to more effectively control the generation of the double exposure area or the unexposure area due to the shot misalignment, thereby alleviating visibility.

### Advantageous Effects

According to the exposure pattern of this disclosure, it is possible to control the generation of the double exposure area or the unexposure area which would be generated when the shot alignment is mismatched, by forming a certain overlapping area during the division exposure and adjusting the areas of the unit pattern areas included in the overlapping area differently, and therefore, the boundary portion visibility problem can be alleviated suitably.

Additionally, according to the exposure pattern of the present disclosure, in terms of being capable of controlling the generation of a double exposure area or an unexposure area by appropriately adjusting the area ratio of the unit pattern areas and/or the width of the overlapping area according to the capability of the exposure apparatus used for exposure, even if a specific exposure apparatus is not used, it is possible to appropriately alleviate the visibility problem of the boundary part.

In addition, it can be used for both positive photo resist and negative photo resist, and the boundary visibility problem can be appropriately alleviated by allowing for appropriately controlling the generation of the double exposure area or the unexposure area according to the kind of the visible portion of each photo resist.

### BRIEF DESCRIPTION OF DRAWINGS

FIG. 1 is a diagram representing a plurality of divided exposure areas included in a single panel, and formed by ideal shot alignment.

FIG. 2 is a diagram showing a double exposure area or an unexposure area generated due to misalignment of shots generated during an actual division exposure process.

FIG. 3 is a diagram illustrating a part of a conventional division exposure pattern for alleviating the boundary visibility problem.

FIG. 4 is a diagram illustrating an unexposure area and a double exposure area generated due to the misalignment of the shot in the conventional division exposure pattern of FIG. 3 in the 9 o'clock direction.

FIG. 5 is a diagram representing an exposure pattern according to an embodiment of the present disclosure.

FIG. 6 is a diagram representing an exposure mask according to an embodiment of the present disclosure.

FIG. 7 is a diagram representing a first overlapping area formed through a first exposure process, and a second overlapping area formed through a second exposure process by an exposure pattern forming method according to an embodiment of the present disclosure.

FIG. 8 is a schematic diagram representing a method for forming an exposure pattern according to an embodiment of the present disclosure.

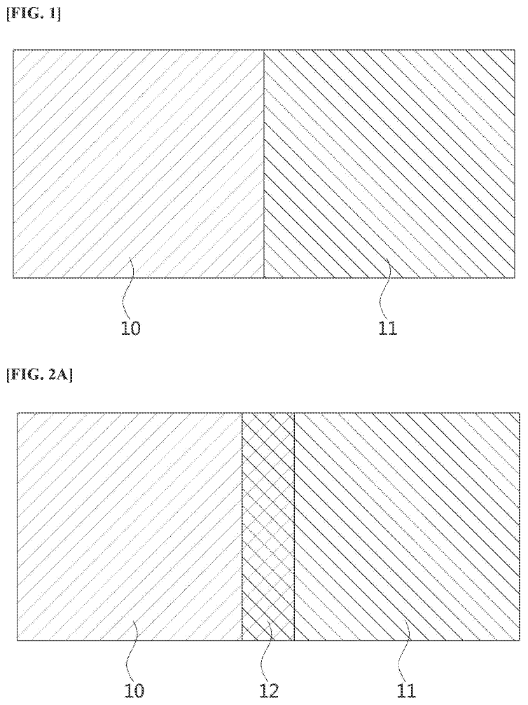

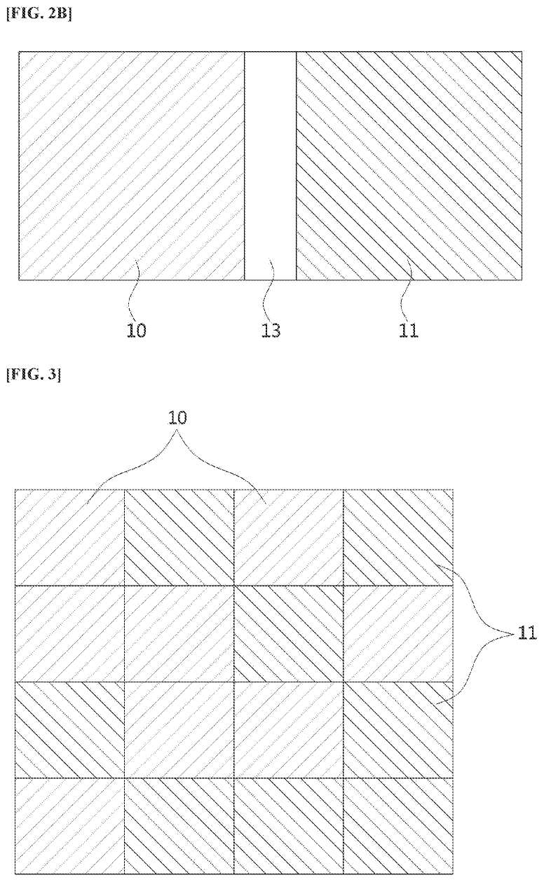

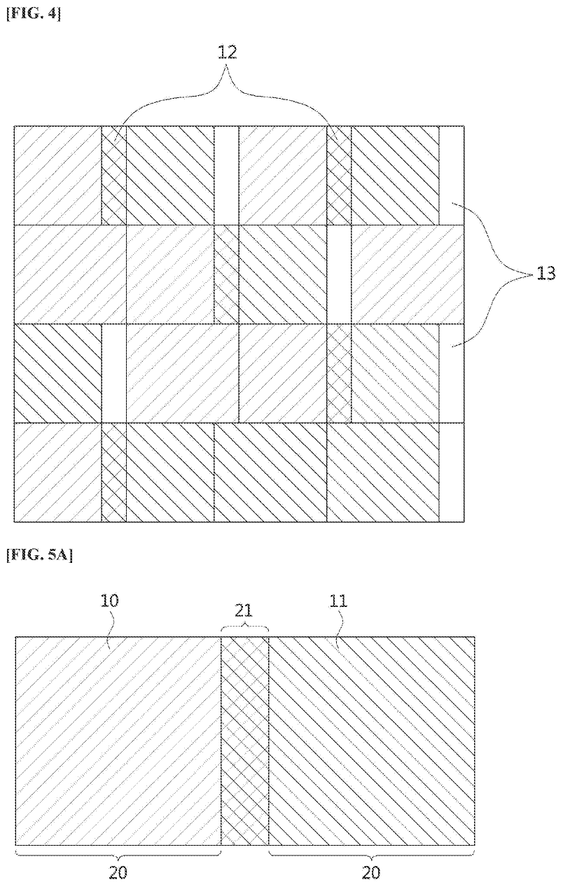

### BEST MODE

The present disclosure relates to an exposure pattern prepared by a division exposure. Specifically, the present disclosure relates to an exposure pattern having different areas of unit pattern areas included in an overlapping area in which adjacent exposure areas overlap, to an exposure mask for preparing the exposure pattern, and to a method for forming an exposure pattern using the same.

More specifically, the present disclosure relates to an exposure pattern formed by a division exposure, wherein in an area where a first exposure area formed by a first exposure and a second exposure area formed by a second exposure overlap each other, an area of at least one of a first unit pattern area constituting the first exposure area and at least one of an area of a second unit pattern area constituting the second exposure area are different from each other.

Additionally, the present disclosure provides an exposure mask for use in a division exposure in which an exposure is carried out with an exposure area being divided into a plurality of areas, the exposure mask including: a non-overlapping exposure portion, a first overlapping exposure portion adjacent to one side of the non-overlapping exposure portion, and a second overlapping exposure portion adjacent to another side of the non-overlapping exposure portion, wherein an area of a first sub-pixel included in the first overlapping exposure portion is different from an area of a second sub-pixel included in the second overlapping exposure portion.

Also, the present disclosure provides a method for forming a division exposure pattern with which an exposure is carried out with an exposure area being divided into a plurality of areas, the method including: forming a first exposure area by performing first exposure using an exposure mask including a non-overlapping exposure portion, a first overlapping exposure portion adjacent to one side of the non-overlapping exposure portion, and a second overlapping exposure portion adjacent to another side of the non-overlapping exposure portion; and forming a second exposure area by performing second exposure using the exposure mask, wherein in an area where a first exposure area formed by a first exposure and a second exposure area formed by a second exposure overlap each other, an area of a first unit pattern area constituting the first exposure area and an area of a second unit pattern area constituting the second exposure area are different from each other.

Hereinafter, preferred embodiments of the present disclosure will be described in detail with reference to classified three items, that is, ^{┌}Exposure Pattern_{┘}, ^{┌}Exposure Mask_{┘}, and ^{┌}Method for Forming Exposure Pattern_{┘}.

Hereinafter, advantages and features of the disclosure, and methods of achieving them will become apparent by referring to the embodiments described below in detail in conjunction with the accompanying drawings.

^{┌}Exposure Pattern^{┘}

The present disclosure is to provide an exposure pattern with alleviated visibility of the boundary during a division exposure, and the exposure pattern means a pattern formed through an exposure process, and specifically, may be a pattern formed by exposing a photo resist through an exposure mask.

The exposure pattern of the present disclosure includes a pattern formed by a division exposure in which an exposure is carried out with an exposure area being divided into a plurality of areas, and is formed by more than one exposure according to the division exposure, so that it may include an overlapping area in which two or more exposures are overlapped, and a non-overlapping area in which a plurality of exposures are not overlapped.

The exposure pattern of the present disclosure is characterized by that in an overlapping area where a first exposure area formed by the first exposure and a second exposure area formed by the second exposure overlap each other, an area of a first unit pattern area constituting the first exposure area and an area of a second unit pattern area constituting the second exposure area are different from each other.

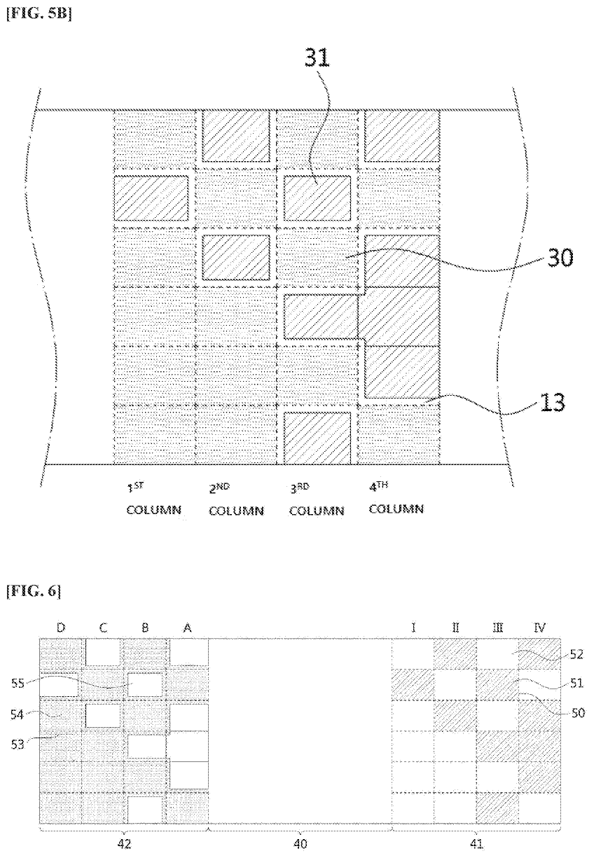

FIG. 5 is a diagram representing an exposure pattern according to an embodiment of the present disclosure.

Hereinafter, the configuration of the present disclosure will be described with reference to FIG. 5, but this is only shown as an example for explaining the present disclosure so that those skilled in the art can clearly understand and easily reproduce it, and the configuration of the present disclosure should not be construed as being limited by the description.

FIG. 5A is a diagram representing a substrate including an exposure pattern formed by division exposure according to an embodiment of the present disclosure.

Referring to FIG. 5A, the non-overlapping area 20 is defined as a portion in which the first exposure area 10 and the second exposure area 11 do not overlap. Additionally, the overlapping area 21 is defined as a portion where the first exposure area 10 and the second exposure area 11 overlap to each other. The overlapping area may be appropriately adjusted according to the capability of the exposure apparatus used, and may be formed to have a width of greater than 0 μm and less than or equal to 50,000 μm.

An area of the first exposure area 10 which is included in the overlapping area 21 is defined as a first overlapping area, and an area of the second exposure area 11 which is included in the overlapping area 21 is defined as a second overlapping area.

FIG. 5B is a diagram representing a pattern of the overlapping area included in the division exposure pattern of FIG. 5A, wherein the overlapping area including the first overlapping area and the second overlapping areas, for example, is partitioned into the divided areas arranged in a 4×6 matrix form, but the present disclosure is not limited to this.

Specifically, referring to FIG. 5B, the first overlapping area includes a plurality of first unit pattern areas 30, and the second overlapping area includes a plurality of second unit pattern areas 31. In the present embodiment, the first unit pattern area 30 and the second unit pattern area 31 include, but are not limited to, a square shape, and may mean an area of a certain shape formed with a straight line and/or a curve. The widths of the first unit pattern area 30 and the second unit pattern area 31 may be appropriately adjusted according to the exposure apparatus used, and is preferably formed to be between 10 μm and 1,000 μm in terms of pattern formation and reduced visibility.

The first overlapping area including the plurality of first unit pattern areas 30 is formed in a portion of the overlapping area. Additionally, the second overlapping area including the plurality of second unit pattern areas 31 is formed in the remaining portion of the overlapping area in which the first overlapping area is not formed.

In this embodiment, the first unit pattern area 30 decreases along a direction from the first exposure area to the second exposure area, and the second unit pattern area 31 decreases along a direction from the second exposure area to the first exposure area.

Specifically, in the first column, five first unit pattern areas 30 are provided, and one second unit pattern area 31 is provided. In the second column, four first unit pattern areas 30 are provided, and two second unit pattern areas 31 are provided. In the third column, three first unit pattern areas 30 are provided, and three second unit pattern areas 31 are provided. In the fourth column, two first unit pattern areas 30 are provided, and four second unit pattern areas 31 are provided.

In this embodiment, the number of columns may be numerous, and accordingly, the number of the first unit pattern areas and the number of the second unit pattern areas may also be numerous, and the direction of increase or decrease of the first unit pattern area and the second unit pattern area may differ depending on the photo resist (PR) and mask used, and the positions of the first unit pattern area and the second unit pattern area included in each column are randomly determined.

The area of the second unit pattern area 31 and the area of the first unit pattern area 30 are different from each other, and specifically, the ratio of the area of the first unit pattern area 30 and the area of the second unit pattern area 31 is preferably between 1:0.7 and 1:1.3 except for 1:1.

In this embodiment, the ratio of the area of the second unit pattern area to the area of the first unit pattern area is less than 1. Accordingly, there is no double exposure area between the first unit pattern area and the second unit pattern area.

In one or more embodiments of the present disclosure, the photo resist (PR) used to form the exposure pattern may employ at least one kind of photo resist (PR) selected from the group consisting of positive photo resists and negative photo resists.

Accordingly, the user appropriately adjusts the ratio of the area of the unit pattern area according to the kind of the photo resist (PR) and the kind of the visible portion among the double exposure area or the unexposure area, so that the visibility problem can be appropriately alleviated by controlling the generation of the visually recognized area among the double exposure area or the unexposure area.

^{┌}Exposure Mask_{┘}

An object of the present disclosure is to provide an exposure mask for forming an exposure pattern with alleviated visibility of the boundary during the division exposure, wherein the exposure mask is for use in a division exposure in which an exposure is carried out with an exposure area being divided into a plurality of areas, the exposure mask including: a non-overlapping exposure portion; a first overlapping exposure portion adjacent to one side of the non-overlapping exposure portion; and a second overlapping exposure portion adjacent to another side of the non-overlapping exposure portion, wherein an area of a first sub-pixel included in the first overlapping exposure portion is different from an area of a second sub-pixel included in the second overlapping exposure portion

The exposure mask of the present disclosure may be for use in the division exposure in which an exposure is carried out with an exposure area being divided into a plurality of areas. Additionally, when the division exposure is carried out, it includes an overlapping exposure portion configured to form a pattern by more than one exposure, and a non-overlapping exposure portion configured to form a pattern by one exposure.

FIG. 6 is a diagram representing an exposure mask according to an embodiment of the present disclosure.

Hereinafter, the exposure mask configuration of the present disclosure will be described with reference to FIG. 6, but this is only shown as an example for explaining the present disclosure so that those skilled in the art can clearly understand and easily reproduce it, and the configuration of the present disclosure should not be construed as being limited by the description.

Referring to FIG. 6, the exposure mask of the present disclosure includes a non-overlapping exposure portion 40; a first overlapping exposure portion 41; and a second overlapping exposure portion 42, wherein when viewed in a plan view, the non-overlapping exposure portion 40 is interposed between the first overlapping exposure portion 41 and the second overlapping exposure portion 42.

Specifically, the first overlapping exposure portion 41 is adjacent to one side of the non-overlapping exposure portion 40, and includes a first pixel portion 51 including a first sub-pixel 50 and a first non-pixel portion 52 that does not include the first sub-pixel 50, and although it is illustrated as being arranged in the form of a 4×6 matrix, this is intended to explain the embodiment of the present disclosure for easier understanding, and in fact, the first overlapping exposure portion may include numerous first pixel portions and first non-pixel portions.

The first pixel portion 51 is disposed in each of the four columns. In this embodiment, the four columns are shown in FIG. 6 as column I, column II, column III, and column IV. In this embodiment, the number of columns may be numerous.

In this embodiment, column I is disposed closest to the non-overlapping exposure portion 40, and column II, column III, and column IV are disposed farther from the non-overlapping exposure portion 40 in that order.

In this embodiment, in order to prevent the boundary from being viewed, the number of first pixel portions included in each column increases with the increased distance from the non-overlapping exposure portion 40 in the first overlapping exposure portions 41, that is, as it goes from column I to column IV. As described above, by increasing the number of the first pixel portions 51 disposed in the first overlapping exposure portion 41 as the distance from the non-overlapping exposure portion 40 increases, the exposure condition at the boundary portion can be prevented from significantly changing.

Specifically, as shown in FIG. 6, one first pixel portion 51 is arranged in column I, two first pixel portions 51 are arranged in column 11, three first pixel portions 51 are arranged in column III, and four first pixel portions 51 are arranged in column IV. In the present embodiment, the locations of the first pixel portions 51 included in each column are randomly determined, and may be numerous depending on the number of columns.

The second overlapping exposure portion 42 is adjacent to another side of the non-overlapping exposure portion 40, and includes a second pixel portion 54 including a second sub-pixel 53 and a second non-pixel portion 55 that does not include the second sub-pixel, and although it is illustrated as being arranged in the form of a 4×6 matrix, this is intended to explain the embodiment of the present disclosure for easier understanding, and in fact, the second overlapping exposure portion 42 may include numerous second pixel portions and second non-pixel portions.

The second pixel portion 54 is disposed in each of the four columns. In this embodiment, the four columns are shown in FIG. 6 as column A, column B, column C, and column D. In this embodiment, the number of columns may be numerous.

In this embodiment, column A is disposed closest to the non-overlapping exposure portion 40, and column B, column C, and column D are disposed farther from the non-overlapping exposure portion 40 in that order.

In this embodiment, in order to prevent the boundary portion from being viewed, the number of second pixel portions 54 included in each column increases with the increased distance from the non-overlapping exposure portion 40 in the second overlapping exposure portions 42, that is, as it goes from column A to column D. As described above, by increasing the number of the second pixel portions 54 disposed in the second overlapping exposure portion 42 as the distance from the non-overlapping exposure portion 40 increases, the exposure condition at the boundary portion can be prevented from significantly changing.

Specifically, as shown in FIG. 6, two second pixel portions 54 are arranged in column A, three second pixel portions 54 are arranged in column B, four second pixel portions 54 are arranged in column C, and five second pixel portions 54 are arranged in column D. In the present embodiment, the locations of the second pixel portions 54 included in each column are randomly determined, and may be numerous depending on the number of columns.

The first pixel portion 51 corresponds to the second non-pixel part 55, and the second pixel portion 54 corresponds to the first non-pixel portion 52.

Specifically, the first pixel portion 51 in column I of the first overlapping exposure portion 41 corresponds to the second non-pixel portion 55 in column D of the second overlapping exposure portion 42, the first pixel portion 51 in column II of the first overlapping exposure portion 41 corresponds to the second non-pixel portion 55 in column C of the second overlapping exposure portion 42, the first pixel portion 51 in column III of the first overlapping exposure portion 41 corresponds to the second non-pixel portion 55 in column B of the second overlapping exposure portion 42, and the first pixel portion 51 in column IV of the first overlapping exposure portion 41 corresponds to the second non-pixel portion 55 in column A of the second overlapping exposure portion 42.

Additionally, the second pixel portion 54 in column A of the second overlapping exposure portion 42 corresponds to the first non-pixel portion 52 in column IV of the first overlapping exposure portion 41, the second pixel portion 54 in column B of the second overlapping exposure portion 42 corresponds to the first non-pixel portion 52 in column III of the first overlapping exposure portion 41, the second pixel portion 54 in column C of the second overlapping exposure portion 42 corresponds to the first non-pixel portion 52 in column II of the first overlapping exposure portion 41, and the second pixel portion 54 in column D of the second overlapping exposure portion 42 corresponds to the first non-pixel portion 52 in column I of the first overlapping exposure portion 41.

In this way, with each correspondence between the pixel portion and the non-pixel portion, the difference in exposure amount between the overlapping exposure portion and the non-overlapping exposure portion can be reduced.

The area of the second sub-pixel 53 formed in the second pixel portion 54 and the area of the first sub-pixel 50 formed in the first pixel portion 51 are different from each other, and specifically, the ratio of the area of the first sub-pixel and the area of the second sub-pixel is preferably between 1:0.7 and 1:1.3 except for 1:1.

In the present embodiment, the ratio of the area of the second sub-pixel 53 to the area of the first sub-pixel 50 is greater than 1.

^{┌}Method for Forming an Exposure Pattern and r Method for Manufacturing a Large-Area Display Panel_{┘}

The present disclosure includes a method for forming an exposure pattern using the above-described exposure mask, and a method for manufacturing a large area display panel including the same.

The method for forming an exposure pattern of the present disclosure may include the step of exposing using the above-described exposure mask. Specifically, the method for forming an exposure pattern of the present disclosure is a division exposure pattern forming method in which the exposure is carried out with an exposure area being divided into a plurality of areas, and includes (a) forming a first exposure area by performing first exposure using an exposure mask including a non-overlapping exposure portion, a first overlapping exposure portion adjacent to one side of the non-overlapping exposure portion, and a second overlapping exposure portion adjacent to another side of the non-overlapping exposure portion; and (b) forming a second exposure area by performing second exposure using the exposure mask, wherein in an area where a first exposure area formed by the first exposure and a second exposure area formed by the second exposure overlap each other, an area of a first unit pattern area constituting the first exposure area and an area of a second unit pattern area constituting the second exposure area are different from each other.

The inventive method may further include, before step (a), forming a metal layer on a substrate divided into a plurality of shot areas, and/or applying a photo resist on the substrate on which the metal layer has been formed, wherein the photo resist may be at least one kind selected from the group consisting of positive photo resists and negative photo resists.

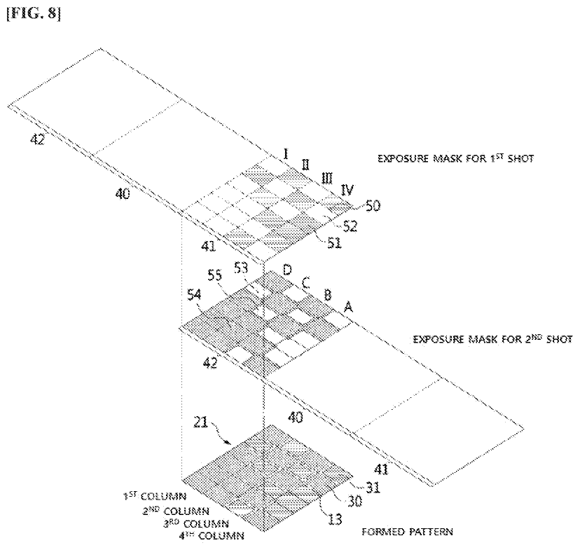

FIG. 8 is a schematic diagram representing a method for forming an exposure pattern according to an embodiment of the present disclosure.

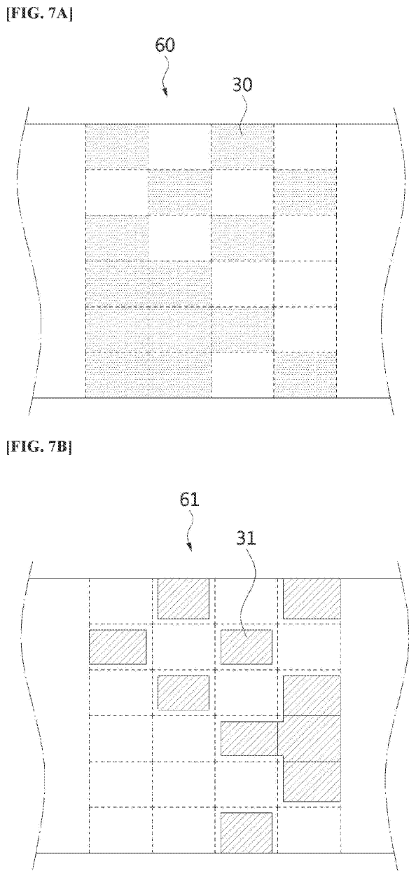

FIG. 7A is a diagram representing a first overlapping area 60 formed through a first exposure process by an exposure pattern forming method according to an embodiment of the present disclosure.

Referring to FIGS. 6, 8 and 7A, the exposure mask shown in FIG. 6 is precisely disposed at a designated location on the substrate, as shown in FIG. 8, on which the photo resist (PR) film has been applied. In this case, the second overlapping exposure portion 42 is covered so that light does not pass therethrough.

Subsequently, as light is injected toward the substrate from the above of the non-overlapping exposure portion 40 and the first overlapping exposure portion 41, the light is injected onto the applied photo resist (PR) through the non-overlapping exposure portion 40 and the first overlapping exposure portion 41.

Thus, a non-overlapping area corresponding to the non-overlapping exposure portion 40 is formed. Additionally, the first overlapping area 60 corresponding to the first overlapping exposure portion 41 is formed as shown in FIG. 7A.

FIG. 7B is a diagram representing a second overlapping area 61 formed through a second exposure process by an exposure pattern forming method according to an embodiment of the present disclosure.

As shown in FIG. 8, the exposure mask is aligned such that the second unit pattern area 31 of the second overlapping area 61 of the photo resist (PR) corresponding to the second overlapping exposure portion 42 of the exposure mask is formed in the remaining partial area of the first overlapping area 60 where the first unit pattern area 30 is not formed. In this case, the first overlapping exposure portion 41 is covered so that light does not pass therethrough.

Subsequently, as light is injected toward the substrate from the above of the non-overlapping exposure portion 40 and the second overlapping exposure portion 42, the light is injected onto the applied photo resist (PR) through the non-overlapping exposure portion 40 and the second overlapping exposure portion 42.

Thus, a non-overlapping area corresponding to the non-overlapping exposure portion 40 is formed. In addition, the second overlapping area 61 corresponding to the second overlapping exposure portion 42 is formed as shown in FIG. 7B, and finally, an exposure pattern as shown in FIGS. 5B and 8 is formed.

When the exposure pattern is formed using the exposure mask as described above, even if the shot alignment is slightly misaligned, the occurrence of a double exposure area can be prevented, so it is possible to alleviate the visibility problem by preventing the occurrence of a portion where visibility is strong due to the double exposure area.

Also, the method for manufacturing a large-area display panel of the present disclosure may further include the step of developing the exposure pattern formed through above-described method using a known method, and a known method other than the above-described contents regarding the formation of an exposure pattern may be utilized.

### INDUSTRIAL APPLICABILITY

According to the exposure pattern of this disclosure, it is possible to control the generation of the double exposure area or the unexposure area which would be generated when the shot alignment is mismatched, by forming a certain overlapping area during the division exposure and adjusting the areas of the unit pattern areas included in the overlapping area differently, and therefore, the boundary portion visibility problem can be alleviated suitably, thereby exhibiting industrial applicability.

1. An exposure pattern formed by a division exposure, wherein in an area where a first exposure area formed by a first exposure and a second exposure area formed by a second exposure overlap each other, an area of a first unit pattern area constituting the first exposure area and an area of a second unit pattern area constituting the second exposure area are different from each other.

2. The exposure pattern of claim 1, wherein a ratio of an area of the first unit pattern area and an area of the second unit pattern area is between 1:0.7 and 1:1.3.

3. The exposure pattern of claim 1, a photo resist (PR) used to form the exposure pattern is at least one kind selected from the group consisting of positive photo resists and negative photo resists.

4. An exposure mask for use in a division exposure in which an exposure is carried out with an exposure area being divided into a plurality of areas, the exposure mask comprising:
a non-overlapping exposure portion; a first overlapping exposure portion adjacent to one side of the non-overlapping exposure portion; and
a second overlapping exposure portion adjacent to another side of the non-overlapping exposure portion,
wherein an area of a first sub-pixel included in the first overlapping exposure portion is different from an area of a second sub-pixel included in the second overlapping exposure portion.

5. The exposure mask of claim 4, wherein a ratio of an area of the first sub-pixel and an area of the second sub-pixel is between 1:0.7 and 1:1.3.

6. A method for forming a division exposure pattern with which an exposure is carried out with an exposure area being divided into a plurality of areas, the method comprising:
forming a first exposure area by performing first exposure using an exposure mask including a non-overlapping exposure portion, a first overlapping exposure portion adjacent to one side of the non-overlapping exposure portion, and a second overlapping exposure portion adjacent to another side of the non-overlapping exposure portion; and
forming a second exposure area by performing second exposure using the exposure mask,
wherein in an area where a first exposure area formed by a first exposure and a second exposure area formed by a second exposure overlap each other, an area of a first unit pattern area constituting the first exposure area and an area of a second unit pattern area constituting the second exposure area are different from each other.
